(19) United States
(12) Patent Application Publication
(10) Pub. No.: US 2026/0196946 A1
(43) Pub. Date: Jul. 9, 2026

(54) SEMICONDUCTOR DEVICE

(71) Applicant: Mitsubishi Electric Corporation, Tokyo (JP)

(72) Inventors: Naoki IKEDA, Tokyo (JP); Kazuya HOKAZONO, Tokyo (JP)

(73) Assignee: Mitsubishi Electric Corporation, Tokyo (JP)

(21) Appl. No.: 19/346,161

(22) Filed: Sep. 30, 2025

(30) Foreign Application Priority Data
Jan. 8, 2025 (JP) 2025-002746

(51) Int. Cl. H02M 7/537; H10D 80/00

(52) U.S. Cl. CPC H02M 7/537; H10D 80/00

(57) ABSTRACT

A semiconductor device includes a high-side IC controlling on/off of an upper arm; and a low-side IC controlling on/off of a lower arm, wherein the low-side IC includes: a first ground terminal connected via a shunt resistor to a main terminal of the lower arm; a first power supply terminal receiving a first power supply based on the first ground terminal; a second ground terminal connected to a connection point between the main terminal and the shunt resistor; a second power supply terminal receiving a second power supply based on the second ground terminal; an input side circuit receiving power from the first power supply terminal; and an output side circuit applying a voltage of the second power supply terminal to a gate terminal of the lower arm; and the second power supply is generated by supplying a current from the first power supply terminal through a diode.

### BACKGROUND

### Field

The present disclosure relates to a semiconductor device.

### BACKGROUND

JP 2021-164176 A discloses a power conversion device including an upper arm switching device and a lower arm switching device connected in series with each other. An upper arm diode is connected in antiparallel to the upper arm switching device. A lower arm diode is connected in antiparallel to the lower arm switching device. The upper arm driver circuit drives the upper arm switching device, and the lower arm driver circuit drives the lower arm switching device.

In an inverter system such as that disclosed in JP 2021-164176 A, the power devices constituting the upper and lower arms receive gate signals from a control IC (Integrated Circuit) and perform on/off operations. Here, a shunt resistor may be connected to the lower arm to detect the current. Current from the source or emitter of the lower arm flows through the shunt resistor to a control ground. At this time, due to the influence of the shunt resistor, the source or emitter potential rises when the lower arm is turned on. This could result in a drop in the gate voltage of the lower arm.

### SUMMARY

The present disclosure has been made to solve the above-mentioned problem, and has an object to provide a semiconductor device that can suppress a decrease in the gate voltage.

The features and advantages of the present disclosure may be summarized as follows.

According to an aspect of the present disclosure, a semiconductor device includes an inverter circuit in which an upper arm and a lower arm are connected in series with each other; a high-side IC configured to control on/off of the upper arm; and a low-side IC configured to control on/off of the lower arm, wherein the low-side IC includes: a first ground terminal connected via a shunt resistor to a main terminal of the lower arm opposite to the upper arm; a first power supply terminal configured to receive a first power supply based on the first ground terminal; a second ground terminal connected to a connection point between the main terminal and the shunt resistor; a second power supply terminal configured to receive a second power supply based on the second ground terminal; a diode having an anode connected to the first power supply terminal and a cathode connected to the second power supply terminal; an input side circuit configured to receive power from the first power supply terminal; and an output side circuit configured to apply a voltage of the second power supply terminal to a gate terminal of the lower arm in response to an input signal for turning on and off the lower arm; and the second power supply is generated by supplying a current from the first power supply terminal through the diode.

Other and further objects, features and advantages of the disclosure will appear more fully from the following description.

### BRIEF DESCRIPTION OF DRAWINGS

FIG. 1 is a diagram showing a configuration of a semiconductor device according to the first embodiment;

FIG. 2 is a diagram illustrating a MOS structure of an input side circuit and an output side circuit according to the first embodiment.

FIG. 3 is a diagram showing a level shift circuit according to the first embodiment;

FIG. 4 is a diagram showing a configuration of a semiconductor device according to a comparative example.

FIG. 5 is a diagram showing a configuration of a semiconductor device according to the second embodiment.

FIG. 6 is a plan view of the semiconductor device according to the second embodiment.

FIG. 7 is a diagram showing a configuration of a semiconductor device according to the third embodiment.

FIG. 8 is a plan view of the semiconductor device according to the third embodiment.

FIG. 9 is a diagram showing the relationship between VNC and GND′u during freewheeling.

FIG. 10 is a diagram showing a signal generating circuit according to the fourth embodiment.

FIG. 11 is a diagram showing a switch control circuit according to the fifth embodiment.

### DESCRIPTION OF EMBODIMENTS

Semiconductor devices according to the respective embodiments will be described with reference to the drawings. The same or corresponding components are denoted by the same reference numerals, and repeated description may be omitted.

### First Embodiment

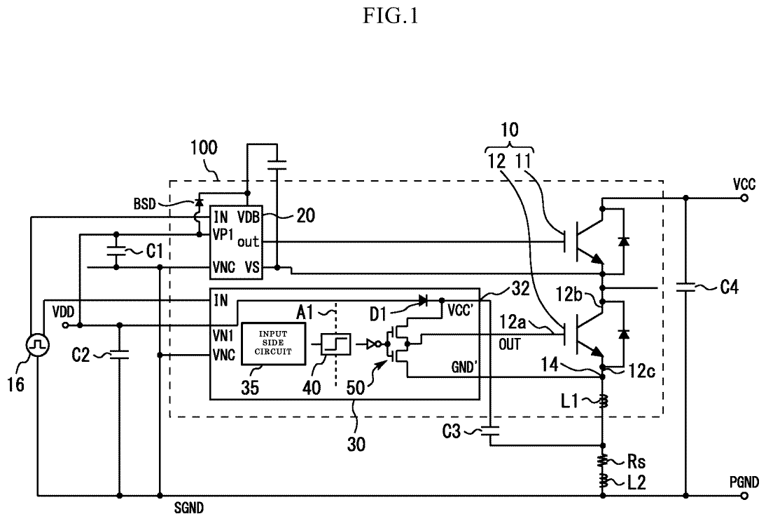

FIG. 1 is a diagram showing a configuration of a semiconductor device 100 according to the first embodiment. The semiconductor device 100 is, for example, an IPM (Intelligent Power Module) in which a switching device and a drive circuit are integrated. The semiconductor device 100 is also called a power conversion device or a power module. The semiconductor device 100 includes an inverter circuit 10 in which an upper arm 11 and a lower arm 12 are connected in series with each other, a high-side IC 20 configured to control the on/off of the upper arm 11, and a low-side IC 30 configured to control the on/off of the lower arm 12.

The upper arm 11 and the lower arm 12 are each a switching device such as an IGBT (Insulated Gate Bipolar Transistor) or a MOSFET (Metal-Oxide-Semiconductor Field-Effect Transistor). The upper arm 11 and the lower arm 12 are also called power devices. In the upper arm 11 and the lower arm 12, diodes are connected in antiparallel to the switching devices. The diode may be configured in the same chip as the switching device, such as an RC-IGBT (Reverse Conductive IGBT). The diode may be a body diode of a MOSFET.

The lower arm 12 has a gate terminal 12a and main terminals 12b and 12c. The main terminal 12b is a collector terminal when the lower arm 12 is an IGBT, and is a drain terminal when the lower arm 12 is a MOSFET. The main terminal 12c is an emitter terminal when the lower arm 12 is an IGBT, and is a source terminal when the lower arm 12 is a MOSFET. A shunt resistor Rs is connected to the main terminal 12c of the lower arm 12 opposite to the upper arm 11. The shunt resistor Rs is used for current detection. A capacitor C4 for supplying a power supply VCC to both ends of the inverter circuit 10 is connected between the collector terminal or drain terminal of the upper arm 11 and the control ground SGND. In addition to the shunt resistor Rs, a parasitic inductance L1 due to an internal pattern of the package and a parasitic inductance L2 due to an external pattern are connected to the main terminal 12c.

The high-side IC 20 has a ground terminal VNC and a power supply terminal VP1. The ground terminal VNC is connected to the control ground SGND. A capacitor C1 for supplying the power supply VDD is connected between the ground terminal VNC and the power supply terminal VP1. A bootstrap diode BSD is connected to the power supply terminal VP1. An input signal is input from a signal source 16 to an input terminal IN of the high-side IC 20. The high-side IC 20 outputs a drive signal from an output terminal OUT to the gate terminal of the upper arm 11 in response to the input signal. This allows the high-side IC 20 to control the on/off of the upper arm 11.

The low-side IC 30 has a first ground terminal VNC, a second ground terminal GND′, a first power supply terminal VN1, a second power supply terminal 32, an input terminal IN, and an output terminal OUT. The first ground terminal VNC is connected to the main terminal 12c of the lower arm 12 via the shunt resistor Rs. The first ground terminal VNC is connected to the control ground SGND. The first power supply terminal VN1 is configured so that the power supply VDD is supplied to it with the first ground terminal VNC as a reference. A capacitor C2 for supplying the power supply VDD is connected between the first power supply terminal VN1 and the first ground terminal VNC. The first power supply terminal VN1 may be connected to the above-mentioned power supply terminal VP1.

The second ground terminal GND′ is connected to a connection point 14 between the main terminal 12c of the lower arm 12 and the shunt resistor Rs. That is, the main terminal 12c of the lower arm 12 and the second ground terminal GND′ are Kelvin connected. The second power supply terminal 32 is configured so that a power supply VCC′ is supplied with reference to the second ground terminal GND′. A capacitor C3 for supplying a power supply VCC′ is connected between the second power supply terminal 32 and the second ground terminal GND′. The capacitor C3 is an external capacitor for charging the gate of the lower arm 12.

An input signal is input from the signal source 16 to an input terminal IN of the low-side IC 30. The low-side IC 30 outputs a drive signal from the output terminal OUT to the gate terminal 12a of the lower arm 12 in response to the input signal. This allows the low-side IC 30 to control the on/off of the lower arm 12.

The low-side IC 30 has a diode D1 whose anode is connected to the first power supply terminal VN1 and whose cathode is connected to the second power supply terminal 32. The power supply VCC′ is generated by receiving a current from the first power supply terminal VN1 via the diode D1. The diode D1 functions as a backflow prevention diode.

The low-side IC 30 includes an input side circuit 35 and an output side circuit 50. The input side circuit 35 is configured to receive power from the first power supply terminal VN1. The input side circuit 35 operates with the first ground terminal VNC as a reference. The input side circuit 35 transmits the input signal input from an input terminal IN to the output side circuit 50. In addition, the input side circuit 35 may have a function of protecting the inverter circuit 10 or a function of matching the delay times of the high-side IC 20 and the low-side IC 30.

The output side circuit 50 is configured to receive power from the second power supply terminal 32. The output side circuit 50 operates with the second ground terminal GND′ as the reference. The output side circuit 50 is configured to apply the voltage of the second power supply terminal 32 to the gate terminal 12a of the lower arm 12 in response to the input signal for turning the lower arm 12 on or off. FIG. 1 shows an example of the output side circuit 50 in which the voltage of the second power supply terminal 32 is applied to the gate terminal 12a via the output terminal OUT in response to the input signal input to the NOT circuit.

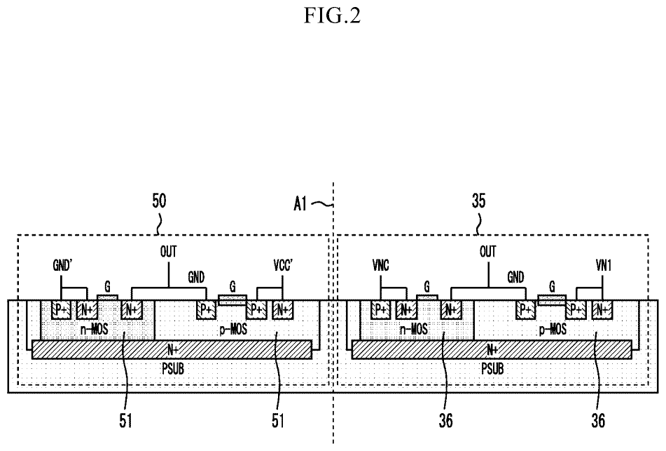

FIG. 2 is a diagram illustrating the MOS structure of the input side circuit 35 and the output side circuit 50 according to the first embodiment. The n-MOS and p-MOS shown in FIG. 2 are examples of any of a plurality of MOS structures that make up the input side circuit 35 and the output side circuit 50. In the low-side IC 30, a diffusion layer 51 forming the output side circuit 50 and a diffusion layer 36 forming the input side circuit 35 are formed independently of each other at the position indicated by the dashed line A1. That is, at the position indicated by the dashed line A1, the CMOS of the input side circuit 35 and the CMOS of the output side circuit 50 are separated, and the input side circuit 35 and the output side circuit 50 can be operated at different reference potentials.

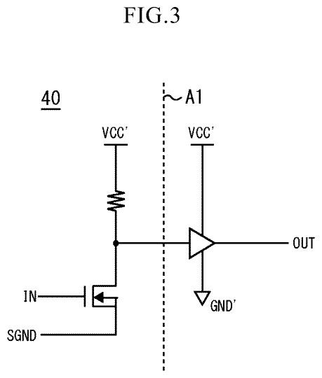

FIG. 3 is a diagram showing a level shift circuit 40 according to the first embodiment. The low-side IC 30 may include the level shift circuit 40 configured to transfer the input signal from the input side circuit 35 to the output side circuit 50. In FIG. 3, the portion of the level shift circuit 40 to the left of the dashed line A1 is formed in the input side circuit 35. The level shift circuit 40 can transmit the input signal input from the input terminal IN from the input side circuit 35 to the output side circuit 50 having different reference potentials. It should be noted that, as long as the input signal input from the input terminal IN can be transmitted from the input side circuit 35 to the output side circuit 50, a circuit other than the circuit shown in FIG. 3 may be employed.

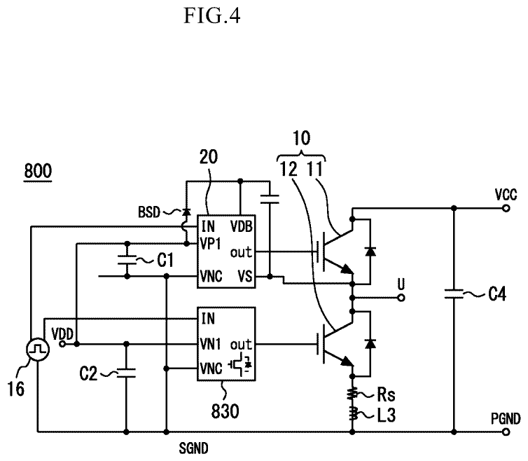

FIG. 4 is a diagram showing the configuration of a semiconductor device 800 according to a comparative example. In the semiconductor device 800, the main terminal of the lower arm 12 is not Kelvin-connected. Furthermore, the low-side IC 830 does not have the second ground terminal GND′ and the second power supply terminal 32. The low-side IC 830 applies the voltage of the power supply terminal VN1 to the gate terminal of the lower arm 12 based on the ground terminal VNC in response to an input signal.

Here, the current from the main terminal of the lower arm flows to the control ground through the shunt resistor Rs and the parasitic inductance L3 due to the pattern. At this time, due to the influence of the shunt resistor Rs or the parasitic inductance L3, when the lower arm 12 is turned on, the potential of the main terminal of the lower arm 12 rises. Therefore, there is a risk that the gate voltage of the lower arm 12 may decrease. This may increase the switching loss of the lower arm 12 depending on the conditions. Furthermore, there is a risk of oscillation occurring due to the influence of parasitic inductance.

In contrast to this, in the semiconductor device 100 according to this embodiment, the capacitor C3 is attached between the main terminal 12c and the second power supply terminal 32. Therefore, the second power supply terminal 32 is supplied with the power supply VCC′ based on the second ground terminal GND′ connected to the connection point 14 between the main terminal 12c of the lower arm and the shunt resistor Rs. The voltage of this second power supply terminal 32 is applied to the gate terminal 12a of the lower arm 12. Therefore, when the lower arm 12 is turned on, the potential of the main terminal 12c rises due to the influence of the shunt resistor Rs and parasitic inductance, and at the same time, the potential of the second power supply terminal 32 also rises. Therefore, the gate voltage of the lower arm 12 can be prevented from decreasing. This makes it possible to prevent the switching speed from becoming slower, and to suppress switching loss. Furthermore, the influence of the parasitic inductance connected to the main terminal 12c of the lower arm 12 can be suppressed. This makes it possible to suppress oscillation and improve the robustness of the system.

Although only one inverter circuit 10 is shown in FIG. 1, the present embodiment may be applied to, for example, a three-phase inverter circuit. In this case, for example, the second power supply terminal 32 from which the power supply VCC′ of the output side circuit 50 is taken out is provided for each of the U, V, and W phases. Furthermore, the configurations of the input side circuit 35, the level shift circuit 40, and the output side circuit 50 described above are merely examples, and they can be replaced with other circuits that have similar functions.

At least one of the upper arm 11 and the lower arm 12 may be formed from a wide bandgap semiconductor. The wide bandgap semiconductor is silicon carbide, a gallium nitride based material or diamond. Even when the power device is made of a wide band gap semiconductor, the same effect as that of this embodiment can be obtained.

The above-described modifications can be applied as appropriate to the semiconductor devices according to the following embodiments. The semiconductor devices according to the following embodiments have many points in common with the first embodiment, so the following description will focus on the differences from the first embodiment.

### Second Embodiment

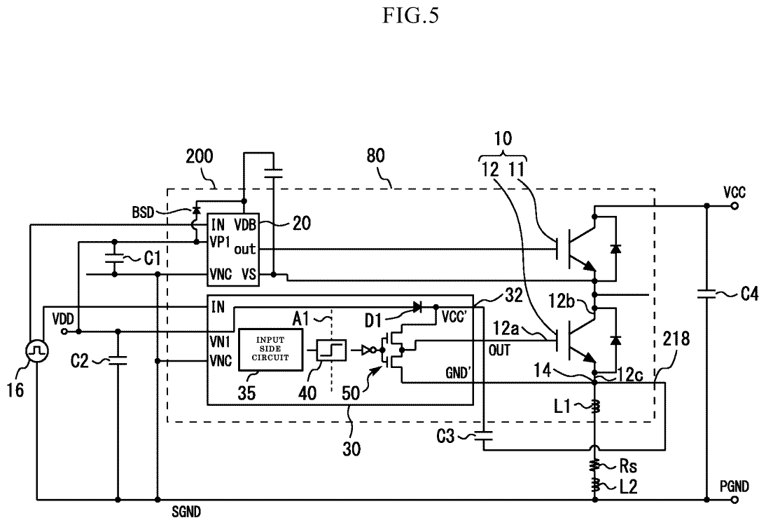

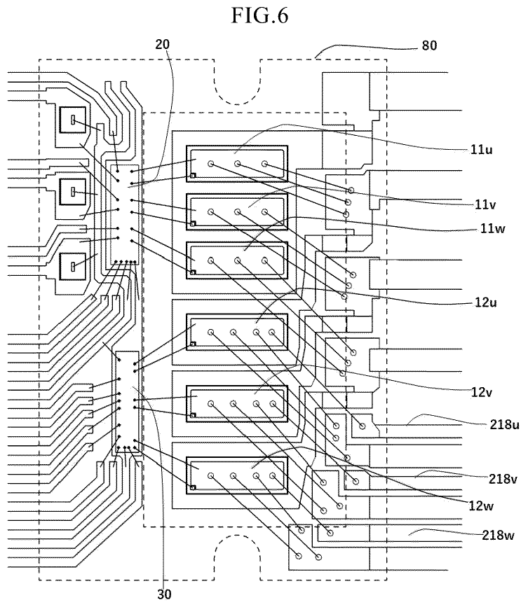

FIG. 5 is a diagram showing a configuration of a semiconductor device 200 according to the second embodiment. FIG. 6 is a plan view of the semiconductor device 200 according to the second embodiment. The package 80 of the semiconductor device 200 includes a sense terminal 218 connected to the main terminal 12c. The second power supply terminal 32 is connected to the connection point 14 via the sense terminal 218 and the capacitor C3. The other configurations are the same as those of the first embodiment.

FIG. 6 shows an example in which the semiconductor device 200 includes a three-phase inverter circuit 10. The high-side IC 20 controls the on/off of the upper arms 11u, 11v, and 11w of the U-phase, V-phase, and W-phase. The low-side IC 30 controls the on/off of the lower arms 12u, 12v, and 12w of the U-phase, V-phase, and W-phase. The sense terminals 218u, 218v, and 218w are connected to the emitter electrodes of the lower arms 12u, 12v, and 12w, respectively. In the case of a MOSFET, the emitter electrode serves as the source electrode.

In this embodiment, by providing the sense terminal 218, the external capacitor C3 can be attached with the potential of the emitter electrode or source electrode of the lower arm 12 as the reference. This makes it possible to reduce the parasitic inductance between the capacitor C3 and the main terminal 12c, including the components inside the package, to approximately zero. Therefore, the decrease in the switching speed of the lower arm 12 and the switching loss can be minimized. Moreover, oscillation can be further suppressed.

### Third Embodiment

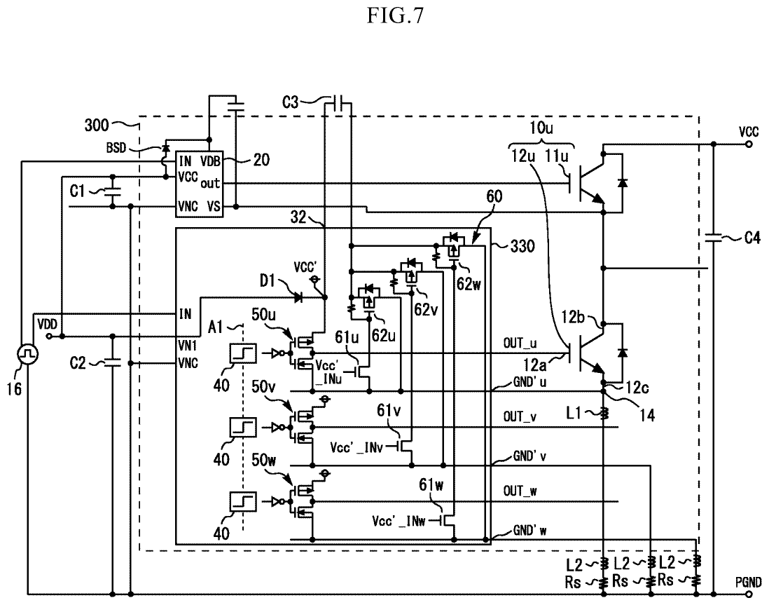

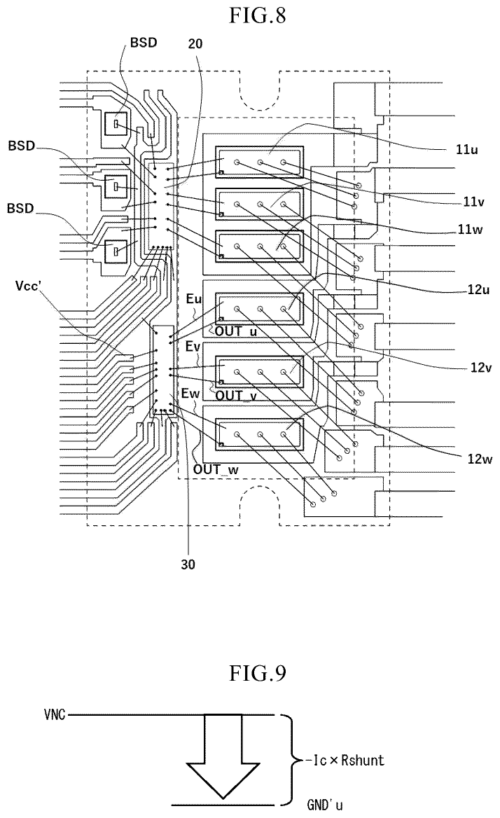

FIG. 7 is a diagram showing a configuration of a semiconductor device 300 according to the third embodiment. FIG. 8 is a plan view of the semiconductor device 300 according to the third embodiment. The semiconductor device 300 includes a plurality of inverter circuits 10. For convenience, FIG. 7 shows only the U-phase inverter circuit 10u of the three-phase inverter circuit 10. The main terminals 12c of the lower arms 12u, 12v, 12w of the U-phase, V-phase, and W-phase are Kelvin-connected. For this reason, as shown in FIG. 7, the low-side IC 330 has second ground terminals GND′u, GND′v, and GND′w for the U-phase, V-phase, and W-phase. As shown in FIG. 8, emitter wirings Eu, Ev, Ew and output wirings OUT_u, OUT_v, OUT_w extend from the lower arms 12u, 12v, 12w, respectively.

A plurality of input signals corresponding to the three-phase inverter circuit 10 are input to the low-side IC 330. In addition, a plurality of output side circuits 50u, 50v, and 50w are provided to correspond to the three-phase inverter circuit 10. The plurality of input signals are input to the plurality of output side circuits 50u, 50v, and 50w via a level shift circuit 40. The plurality of output side circuits 50u, 50v, 50w are configured to apply the voltage of the second power supply terminal 32 to the gate terminals 12a of the lower arms 12 of the plurality of inverter circuits 10 in accordance with the plurality of input signals corresponding to the plurality of inverter circuits 10.

The low-side IC 330 has one second power supply terminal 32 and one switch circuit 60. The switch circuit 60 is composed of, for example, switching devices 61u and 62u connected to the output side circuit 50u, switching devices 61v and 62v connected to the output side circuit 50v, and switching devices 61w and 62w connected to the output side circuit 50w. In this way, the switch circuit can be configured with, for example, an NMOS.

The switching device 61u receives a signal Vcc′_INu, which is a U-phase input signal converted by the level shift circuit 40. The signal Vcc′_INu is a signal synchronized with the input signal. Therefore, when the lower arm 12u of the U phase is turned on, the switching devices 61u and 62u are turned on. That is, when an ON signal for turning on the lower arm 12u is input as the signal Vcc′_INu to the switching device 61u, the connection point 14 of the inverter circuit 10u and the second power supply terminal 32 are connected via the capacitor C3. The V-phase and W-phase operate in the same manner.

That is, the switch circuit 60 is configured to connect the connection point 14 of any one of the plurality of inverter circuits 10 to the second power supply terminal 32 in response to the plurality of input signals. Specifically, the switch circuit 60 connects the connection point 14 of one of the multiple inverter circuits 10 to which an ON signal that turns on the lower arm 12 is input as the corresponding input signal, to the second power supply terminal 32.

The switch circuit 60 of this embodiment connects the power device that is turned on to the capacitor C3. Therefore, only when the potential of the main terminal 12c of the power device becomes high, the main terminal 12c and the capacitor C3 are connected, and the potential of the second power supply terminal 32 rises. Therefore, in this embodiment, the function of the first embodiment can be realized with only one second power supply terminal 32. This reduces the number of terminals required for the power module. Furthermore, only one capacitor C3 is required. Therefore, the power module including the semiconductor device 300 and the peripheral capacitors and the like can be miniaturized. Furthermore, the wiring pattern from the pin of the second power supply terminal 32 to the capacitor C3 can be simplified. For example, the power supply for the first power supply terminal VN1 may be supplied from the power supply terminal VP1 of the high-side IC 20, and the second power supply terminal 32 may be provided at the position of the first power supply terminal VN1.

### Fourth Embodiment

FIG. 9 is a diagram showing the relationship between VNC and GND′u during freewheeling. During freewheeling, the potential of the second ground terminal GND′u becomes lower than the potential of the first ground terminal VNC. Therefore, for example, in the third embodiment, when an ON signal is input to the power device during freewheeling, the capacitor C3 and the connection point 14 are connected even in a state such as that shown in FIG. 9 where the potential of the second ground terminal GND′u is low. For this reason, it is difficult to apply a control method with synchronous rectification, that is, a control method in which an ON signal is input to a power device during freewheeling, to the third embodiment.

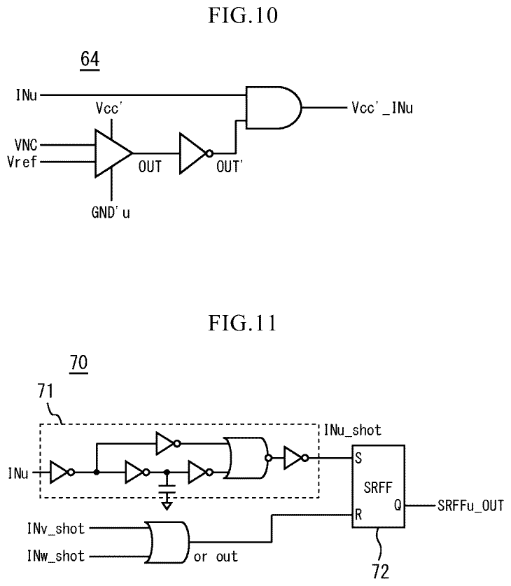

FIG. 10 is a diagram showing a signal generating circuit 64 according to the fourth embodiment. To address the above problem, the switch circuit 60 of this embodiment generates the signal Vcc′_INu using the signal generation circuit 64. The operation of the signal generating circuit 64 will be described below using the U phase as an example, but the V-phase and W-phase signals Vcc′_INv and Vcc′_INw can also be generated by a similar circuit.

In the signal generating circuit 64, a comparator determines whether the voltage of the first ground terminal VNC exceeds a predetermined reference voltage Vref, using the potential of the second ground terminal GND′u as a reference. The reference voltage Vref may be set so that the connection point 14 corresponding to the inverter circuit 10u is not connected to the second power supply terminal 32 during the freewheeling operation of the inverter circuit 10u. As shown in FIG. 9, during freewheeling operation, the potential of GND′u drops by −Ic×Rs relative to the potential of VNC. Therefore, it is possible to determine whether or not the freewheeling operation is occurring based on the VNC potential as viewed from the GND′u potential. The signal generating circuit 64 is configured to output the signal Vcc′_INu synchronized with the input signal INu only when it is determined that the current is not in the freewheeling mode.

In other words, the switch circuit 60 connects the connection point 14 of the inverter circuit 10 among the multiple inverter circuits 10u, 10v, 10w, which receives an ON signal as its corresponding input signal and whose corresponding first ground terminal VNC has a voltage lower than the reference voltage Vref, to the second power supply terminal 32. As a result, the capacitor C3 and the connection point 14 are connected only when the power device is in the on state with forward current flow. Therefore, even in a control system that includes synchronous rectification, the circuit configuration with one second power supply terminal 32 can be adopted. Therefore, the power module can be made smaller.

### Fifth Embodiment

FIG. 11 is a diagram showing a switch control circuit 70 according to the fifth embodiment. The switch control circuit 70 is disposed in the low-side IC 330 in the preceding stage of the switch circuit 60. The signal SRFFu_OUT in FIG. 11 is input to the switch circuit 60 as the signal Vcc′_INu in FIG. 7. Here, the operation of the switch control circuit 70 will be described using the U phase as an example, but the V-phase and W-phase signals Vcc′_INv and Vcc′_INw can also be generated by a similar circuit.

In the switch control circuit 70, an SRFF (flip-flop) 72 is arranged in the preceding stage of the switch circuit 60. When an ON signal is input as the U-phase input signal INu, the shot pulse generating circuit 71 generates a shot pulse INu_shot and inputs it to Set of the U-phase SRFF 72. As a result, the signal SRFFu_OUT is turned on, and the U-phase connection point 14 and the capacitor C3 are connected. Similarly, shot pulses INv_shot and INw_shot are generated in the V-phase and W-phase. The V-phase and W-phase shot pulses INv_shot and INw_shot are input to the Reset of the U-phase SRFF 72. This turns off the signal SRFFu_OUT.

In this way, when an ON signal that turns on the corresponding lower arm 12u is input as one input signal INu out of the plurality of input signals INu, INv, and INw, the switch control circuit 70 outputs the ON output SRFFu_OUT to the switch circuit 60. This on output SRFFu_OUT connects the connection point 14 of the inverter circuit 10 u corresponding to the input signal INu to the second power supply terminal 32. Furthermore, when an ON signal that turns on the corresponding lower arm 12 is input as the input signal INv or INw other than the input signal INu, the switch control circuit 70 stops the ON output SRFFu_OUT.

In this embodiment, when the capacitor C3 and the connection point 14 are connected in one phase, if an ON signal is input for another phase, the connection between the capacitor C3 and the connection point 14 is released. This makes it possible to prevent the second ground terminals GND′u, GND′v, and GND′w from shorting out. Therefore, even in a control method in which multiple phases are turned on simultaneously, the circuit configuration with one second power supply terminal 32 can be adopted. Therefore, the power module can be made smaller.

The determination of the freewheeling operation in the fourth embodiment may be combined with this embodiment. The technical features described in each embodiment may be used in appropriate combination.

Various aspects of the present disclosure are summarized below as appendices.

### Appendix 1

A Semiconductor Device Comprising:
an inverter circuit in which the upper arm and the lower arm are connected in series with each other;
a high-side IC configured to control on/off of the upper arm; and
a low-side IC configured to control on/off of the lower arm, wherein
the low-side IC includes:
a first ground terminal connected via a shunt resistor to a main terminal of the lower arm opposite to the upper arm;
a first power supply terminal configured to receive a first power supply based on the first ground terminal;
a second ground terminal connected to a connection point between the main terminal and the shunt resistor;
a second power supply terminal configured to receive a second power supply based on the second ground terminal;
a diode having an anode connected to the first power supply terminal and a cathode connected to the second power supply terminal;
an input side circuit configured to receive power from the first power supply terminal; and
an output side circuit configured to apply a voltage of the second power supply terminal to a gate terminal of the lower arm in response to an input signal for turning on and off the lower arm; and
the second power supply is generated by supplying a current from the first power supply terminal through the diode.

### Appendix 2

The semiconductor device according to appendix 1, wherein in the low-side IC, a diffusion layer forming the output side circuit and a diffusion layer forming the input side circuit are formed independently.

### Appendix 3

The semiconductor device according to appendix 1 or 2, wherein the low-side IC includes a level shift circuit configured to transfer the input signal from the input side circuit to the output side circuit.

### Appendix 4

The semiconductor device according to any one of appendixes 1 to 3, wherein a package of the semiconductor device includes a sense terminal connected to the main terminal, and
the second power supply terminal is connected to the connection point via the sense terminal.

### Appendix 5

The semiconductor device according to any one of appendixes 1 to 4, further comprising:
a plurality of the inverter circuits; wherein
the low-side IC includes:
one of the second power supply terminal;
a plurality of the output-side circuits provided corresponding to the plurality of inverter circuits and configured to apply the voltage of the second power supply terminal to the gate terminals of the lower arms of the plurality of inverter circuits in response to a plurality of the input signals corresponding to the plurality of inverter circuits; and
a switch circuit configured to connect the connection point of any one of the plurality of inverter circuits to the second power supply terminal in response to the plurality of input signals;

### Appendix 6

The semiconductor device according to appendix 5, wherein the switch circuit connects the connection point of an inverter circuit, among the plurality of inverter circuits, to which an ON signal that turns on the lower arm is input as the input signal corresponding to the inverter circuit, to the second power supply terminal.

### Appendix 7

The semiconductor device according to appendix 6, wherein the switch circuit connects the connection point of an inverter circuit, among the plurality of inverter circuits, to which the ON signal is input as the input signal corresponding to the inverter circuit, and which the first ground terminal corresponding to the inverter circuit has a voltage lower than a predetermined reference voltage, to the second power supply terminal, and
the predetermined reference voltage is set so that the connection point corresponding to the inverter circuit and the second power supply terminal are not connected when the inverter circuit is in a freewheeling operation.

### Appendix 8

The semiconductor device according to any one of appendixes 5 to 7, wherein the low-side IC has a switch control circuit,
when an ON signal for turning on a corresponding lower arm is input as one input signal of the plurality of input signals, the switch control circuit performs an ON output to the switch circuit for connecting the connection point of an inverter circuit of the plurality of inverter circuits corresponding to the one input signal to the second power supply terminal, and
when an ON signal for turning on a corresponding lower arm is input as an input signal other than the one input signal among the plurality of input signals, the switch control circuit stops the ON output.

### Appendix 9

The semiconductor device according to any one of appendixes 1 to 8, wherein at least one of the upper arm and the lower arm is made with a wide bandgap semiconductor.

### Appendix 10

The semiconductor device according to appendix 9, wherein the wide band gap semiconductor is silicon carbide, gallium nitride-based material, or diamond.

The second power supply terminal of the semiconductor device according to the present disclosure is supplied with the second power supply based on the second ground terminal connected to the connection point between the main terminal of the lower arm and the shunt resistor. The voltage of this second power supply terminal is applied to the gate terminal of the lower arm. At this time, when the lower arm is turned on, the potential of the main terminal rises due to the influence of the shunt resistor, and the potential of the second power supply terminal also rises. This makes it possible to prevent the gate voltage of the lower arm from decreasing.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2025-002746, filed on Jan. 8, 2025 including specification, claims, drawings and summary, on which the Convention priority of the present application is based, are incorporated herein by reference in its entirety.

1. A semiconductor device comprising:
an inverter circuit in which the upper arm and the lower arm are connected in series with each other;
a high-side IC configured to control on/off of the upper arm; and
a low-side IC configured to control on/off of the lower arm, wherein
the low-side IC includes:
a first ground terminal connected via a shunt resistor to a main terminal of the lower arm opposite to the upper arm;
a first power supply terminal configured to receive a first power supply based on the first ground terminal;
a second ground terminal connected to a connection point between the main terminal and the shunt resistor;
a second power supply terminal configured to receive a second power supply based on the second ground terminal;
a diode having an anode connected to the first power supply terminal and a cathode connected to the second power supply terminal;
an input side circuit configured to receive power from the first power supply terminal; and
an output side circuit configured to apply a voltage of the second power supply terminal to a gate terminal of the lower arm in response to an input signal for turning on and off the lower arm; and
the second power supply is generated by supplying a current from the first power supply terminal through the diode.

2. The semiconductor device according to claim 1, wherein in the low-side IC, a diffusion layer forming the output side circuit and a diffusion layer forming the input side circuit are formed independently.

3. The semiconductor device according to claim 1, wherein the low-side IC includes a level shift circuit configured to transfer the input signal from the input side circuit to the output side circuit.

4. The semiconductor device according to claim 1, wherein a package of the semiconductor device includes a sense terminal connected to the main terminal, and
the second power supply terminal is connected to the connection point via the sense terminal.

5. The semiconductor device according to claim 1, further comprising:
a plurality of the inverter circuits; wherein
the low-side IC includes:
one of the second power supply terminal;
a plurality of the output-side circuits provided corresponding to the plurality of inverter circuits and configured to apply the voltage of the second power supply terminal to the gate terminals of the lower arms of the plurality of inverter circuits in response to a plurality of the input signals corresponding to the plurality of inverter circuits; and
a switch circuit configured to connect the connection point of any one of the plurality of inverter circuits to the second power supply terminal in response to the plurality of input signals;

6. The semiconductor device according to claim 5, wherein the switch circuit connects the connection point of an inverter circuit, among the plurality of inverter circuits, to which an ON signal that turns on the lower arm is input as the input signal corresponding to the inverter circuit, to the second power supply terminal.

7. The semiconductor device according to claim 6, wherein the switch circuit connects the connection point of an inverter circuit, among the plurality of inverter circuits, to which the ON signal is input as the input signal corresponding to the inverter circuit, and which the first ground terminal corresponding to the inverter circuit has a voltage lower than a predetermined reference voltage, to the second power supply terminal, and
the predetermined reference voltage is set so that the connection point corresponding to the inverter circuit and the second power supply terminal are not connected when the inverter circuit is in a freewheeling operation.

8. The semiconductor device according to claim 5, wherein the low-side IC has a switch control circuit,
when an ON signal for turning on a corresponding lower arm is input as one input signal of the plurality of input signals, the switch control circuit performs an ON output to the switch circuit for connecting the connection point of an inverter circuit of the plurality of inverter circuits corresponding to the one input signal to the second power supply terminal, and
when an ON signal for turning on a corresponding lower arm is input as an input signal other than the one input signal among the plurality of input signals, the switch control circuit stops the ON output.

9. The semiconductor device according to claim 1, wherein at least one of the upper arm and the lower arm is made with a wide bandgap semiconductor.

10. The semiconductor device according to claim 9, wherein the wide band gap semiconductor is silicon carbide, gallium nitride-based material, or diamond.
